(19) United States
(12) Patent Application Publication
(10) Pub. No.: US 2023/0309361 A1
(43) Pub. Date: Sep. 28, 2023

(54) SEMICONDUCTOR DEVICE, DISPLAY DEVICE, PHOTOELECTRIC CONVERSION DEVICE, ELECTRONIC EQUIPMENT, ILLUMINATING DEVICE, AND MOBILE OBJECT

(71) Applicant: CANON KABUSHIKI KAISHA, Tokyo (JP)

(72) Inventor: HIDEMASA OSHIGE, Kanagawa (JP)

(21) Appl. No.: 18/185,453

(22) Filed: Mar. 17, 2023

(30) Foreign Application Priority Data
Mar. 24, 2022 (JP) 2022-048568

(51) Int. Cl. H10K 59/80

(52) U.S. Cl. CPC H10K 59/8722; F21S 43/14

(57) ABSTRACT

A semiconductor device has an element substrate having a first region provided with a functional element provided, and a second region of a peripheral region in a periphery of the first region; an opposed substrate arranged so as to be superposed on at least a part of the second region and the first region in a plan view; a resin layer arranged between the opposed substrate and the second region, and for bonding the opposed substrate and the second region; and a driving circuit chip joined with the second region. The driving circuit chip has a region superposed on the opposed substrate in the plan view, and the driving circuit chip has a region separated from the first region by a longer distance than a distance between the first region and the resin layer, and not superposed on the resin layer in the plan view.

### BACKGROUND OF THE INVENTION

### Field of the Invention

The present invention relates to a semiconductor device, a display device, a photoelectric conversion device, electronic equipment, an illuminating device, and a mobile object.

### Description of the Related Art

In a display device of one aspect of a semiconductor device, a translucent sheet (an opposed substrate) opposed to a display substrate (element substrate) may be provided in order to protect the display substrate.

Further, with a trend toward a higher definition of a display device, the display device has been demanded to be improved in processing speed. For this reason, mounting of a highly integrated driving circuit chip on the display device (chip-on-chip mounting) may be adopted.

However, with chip-on-chip mounting, the bonding region of a translucent sheet and the mounting region of a driving circuit chip are required to be separately provided on a display substrate. For this reason, the space (frame) in the peripheral region disposed at the outside portion of the display region may be large. Further, the joint part between the driving circuit chip and the display substrate tends to be damaged by an external stress. As a result, poor conduction may be caused in the display device.

Japanese Patent Application Publication No. 2004-117526 discloses a display device including an element substrate, which is joined with a driving circuit chip, and a translucent sheet bonded to each other by an adhesive. In Japanese Patent Application Publication No. 2004-117526, a driving circuit chip is accommodated in the space inside, which is surrounded by the element substrate, the translucent sheet (opposed substrate), and the adhesive, so that the heat generated at the driving circuit chip is less likely to be radiated. For example, with a device of which characteristics are deteriorated by heat as with an organic EL display device, the heat from the driving circuit chip may reduce the image quality (the photographing quality or the display quality) of the display device.

### SUMMARY OF THE INVENTION

Under such circumstances, it is an object of the disclosure of the present technology to provide a semiconductor device of which damage and characteristic deterioration are suppressed.

An aspect of the disclosure is a semiconductor device including: an element substrate having a first region provided with a functional element, and a second region which is a peripheral region in a periphery of the first region; an opposed substrate arranged so as to be superposed on the first region and at least a part of the second region in a plan view with respect to a main surface of the element substrate; a resin layer arranged between the opposed substrate and the second region, and for bonding the opposed substrate and the second region; and a driving circuit chip joined with the second region, wherein the driving circuit chip has a region superposed on the opposed substrate in the plan view, and the driving circuit chip has a region separated from the first region by a longer distance than a distance between the first region and the resin layer, the region being not superposed on the resin layer in the plan view.

Further features of the present invention will become apparent from the following description of exemplary embodiments with reference to the attached drawings.

### BRIEF DESCRIPTION OF THE DRAWINGS

FIGS. 1A and 1B are each a view showing a semiconductor device in accordance with embodiment 1;

FIGS. 2A to 2E are each a view for illustrating a method for manufacturing the semiconductor device in accordance with embodiment 1;

FIGS. 3A and 3B are each a view showing a semiconductor device in accordance with embodiment 2;

FIGS. 4A and 4B are each a view showing a semiconductor device in accordance with embodiment 3;

FIGS. 5A and 5B are each a view showing a semiconductor device in accordance with embodiment 4;

FIG. 6 is a schematic view showing one example of a display device in accordance with embodiment 5;

FIG. 7A is a schematic view showing one example of an image pick-up device in accordance with embodiment 5;

FIG. 7B is a schematic view showing one example of electronic equipment;

FIGS. 8A and 8B are each a schematic view showing one example of a display device in accordance with embodiment 5;

FIG. 9A is a schematic view showing one example of an illuminating device in accordance with embodiment 5;

FIG. 9B is a schematic view showing one example of an automobile in accordance with embodiment 5; and

FIGS. 10A and 10B are each a schematic view showing one example of a wearable device in accordance with embodiment 5.

### DESCRIPTION OF THE EMBODIMENTS

Below, referring to the accompanying drawings, aspects for carrying out the technology of the present matter. Incidentally, in the following description and drawings, the configuration common among a plurality of drawings are given common reference numeral and sign. For this reason, the common configuration will be described by cross-reference to the plurality of drawings, and the description on the configurations given common reference numeral and sign will be appropriately omitted. Incidentally, in each embodiment, the “distance” between two configurations represents the length of the interval (minimum distance) between two configurations. Therefore, when two configurations are in contact with each other, the distance between the two configurations is 0.

### Embodiment 1

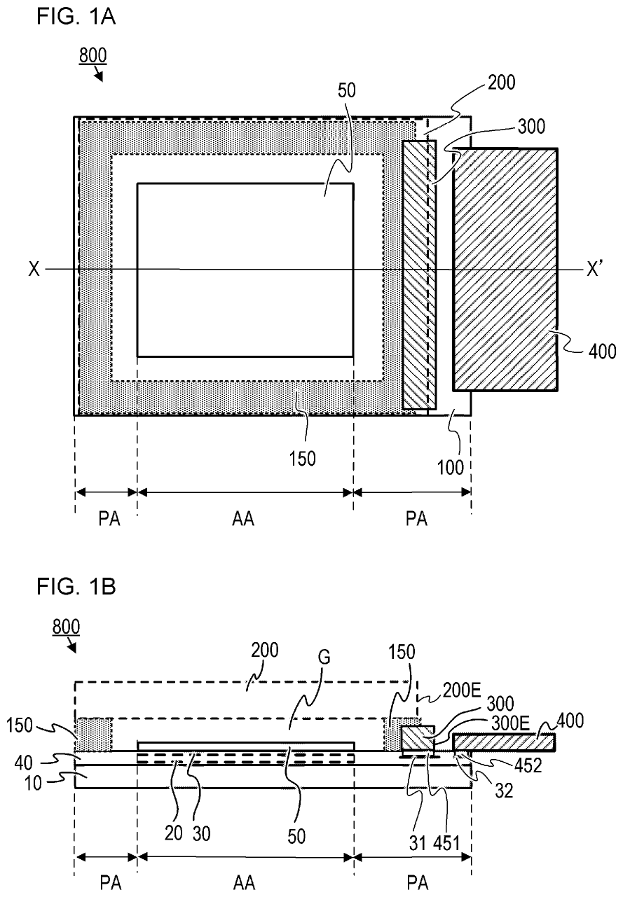

FIG. 1A shows a plan view of a semiconductor device 800 (semiconductor element) in accordance with embodiment 1. The semiconductor device 800 is, for example, a display device (display element) or a photoelectric conversion device (photoelectric conversion element). Incidentally, the term “the plan view” represents the view of the semiconductor device 800 from the direction perpendicular to the main surface of an element substrate 100 (the direction normal to the main surface; lamination direction). Incidentally, in a plan view, the plurality of members overlapping one another in the direction perpendicular to the main surface of the element substrate 100 are assumed to be able to be seen therethrough. For example, in a plan view, an opposed substrate 200 overlaps an element substrate 100 (functional element 50). The direction (opposed direction) in which the opposed substrate 200 is opposed to the element substrate 100 is the direction perpendicular to the main surface of the element substrate 100 (the direction normal to the main surface).

The element substrate 100 has an effective element region AA and a peripheral region PA on a first main surface of a substrate 10 described later (see FIG. 1B). In the effective element region AA, an effective element is provided. The effective element region AA is a quadrilateral region. The diagonal length of the effective element region AA is, for example, 5 to 50 mm. The peripheral region PA is a region situated in the periphery of the effective element region AA.

The peripheral region PA includes, for example, a peripheral circuit region (not shown) including a peripheral circuit provided therein. When the semiconductor device 800 is a display device, the peripheral circuit includes, for example, a processing circuit (a circuit for processing a signal to be inputted to an effective pixel) such as a driving circuit (circuit for driving an effective pixel) or a DAC (digital-analog conversion circuit). Further, the peripheral region PA is situated outside the effective element region AA, and includes, for example, a non-effective element region (not shown) provided with a non-effective element. The non-effective element is an element not functioning as an effective element (e.g., a dummy element, a reference element, a test element, or a monitor element).

A resin layer 150 is arranged between the opposed substrate 200 and the element substrate 100, and bonds the opposed substrate 200 and the element substrate 100. The resin layer 150 is provided in the peripheral region PA of the element substrate 100. The resin layer 150 surrounds the effective element region AA in a plan view. In the peripheral region PA, a driving circuit chip 300 is electrically connected with the element substrate 100. As shown in FIG. 1A, in a plan view, the driving circuit chip 300 overlaps the opposed substrate 200, the element substrate 100, and the resin layer 150. In the region outside the region bonded with the driving circuit chip 300 of the peripheral region PA, a wiring substrate 400 is electrically connected with the element substrate 100. Then, in a plan view, a part of the wiring substrate 400 overlaps the element substrate 100.

FIG. 1B is a cross sectional view of the semiconductor device 800 along line X-X′ of FIG. 1A. The semiconductor device 800 has the element substrate 100, the opposed substrate 200, the driving circuit chip 300, the wiring substrate 400, and the resin layer 150. Herein, with the configuration provided in the peripheral region PA, the resin layer 150, the driving circuit chip 300, and the wiring substrate 400 are closer to the effective element region AA (shorter in distance from the effective element region AA) in this order.

The element substrate 100 has a substrate 10, a semiconductor element 20, a wiring layer 30, a first terminal part 31, a second terminal part 32, an interlayer insulation layer 40, and a functional element 50. In the effective element region AA of the element substrate 100, the semiconductor element 20, the wiring layer 30, and the functional element 50 are provided. In the peripheral region PA of the element substrate 100, the first terminal part 31, the second terminal part 32, and the peripheral circuit (not shown) are provided.

The opposed substrate 200 is opposed to the element substrate 100 via a gap G. Herein, the opposed substrate 200 is, in a plan view, opposed to the element substrate 100 so as to cover the whole of the effective element region AA and a part of the peripheral region PA. Then, in the cross sectional view shown in FIG. 1B, the outer end 200E of the opposed substrate 200 is situated right above the driving circuit chip 300. In other words, in a plan view, a part of the opposed substrate 200 is superposed on the driving circuit chip 300.

For the opposed substrate 200, a given material (e.g., glass or acrylic) can be used so long as it has optical transparency. However, in embodiment 1, non-alkali glass is used. The thickness of the opposed substrate 200 is, for example, 0.7 mm.

Further, on the main surface (both the main surfaces or either main surface of both the main surfaces) of the opposed substrate 200, an antireflection film (AR film) may be formed. Due to the formation of an antireflection film on the main surface of the opposed substrate 200, the light incidence efficiency to the functional element 50 increases when the functional element 50 is a photoelectric conversion element. On the other hand, when the functional element 50 is a display element, the functional element 50 can extract a display light with efficiency.

The driving circuit chip 300 is a semiconductor chip including a driving circuit provided therein. The driving circuit chip 300 is bonded to the element substrate 100. The driving circuit chip 300 is electrically connected with the element substrate 100 via the first terminal part 31 and the joint member 451. Further, the surface opposed to the element substrate 100 of the driving circuit chip 300 is provided with a joint electrode (not shown) such as an Au bump.

Herein, some region near the effective element region AA of the driving circuit chip 300 is covered with the resin layer 150. In other words, in a plan view, the driving circuit chip 300 has a superposing region superposed with the resin layer 150. Further, the driving circuit chip 300 has a region not superposed with the resin layer 150 in a plan view at a position away from the effective element region AA by a longer distance than the distance between the effective element region AA and the superposing region (resin layer 150). Then, the driving circuit chip 300 is exposed from the resin layer 150 in the region not superposed with the resin layer 150, in a plan view.

The wiring substrate 400 is a flexible circuit substrate provided with a wiring pattern (such as a glass epoxy substrate or a polyimide film). The surface opposed to the element substrate 100 of the wiring substrate 400 is provided with a copper electrode (not shown).

The wiring substrate 400 is joined with the element substrate 100 in the region further outside the region joined with the driving circuit chip 300 of the element substrate 100. The semiconductor device 800 can be electrically connected with an external power source (not shown) via the wiring substrate 400. The wiring substrate 400 is electrically connected with the element substrate 100 via the second terminal part 32 and the joint member 452. Furthermore, the driving circuit chip 300 and the wiring substrate 400 are electrically connected with each other via the first terminal part 31, the second terminal part 32, the joint member 451, and the joint member 452. Incidentally, the joint member 451 and the joint member 452 are conductive materials such as solder or ACF (anisotropic conductive film; anisotropic conductive resin).

The resin layer 150 is provided in the peripheral region PA of the element substrate 100, and bonds the element substrate 100 and the opposed substrate 200. The resin layer 150 further covers the end (one end) on the effective element region AA side of the driving circuit chip 300. On the other hand, the outer end 300E of the end closer to the outer end of the element substrate 100 of the driving circuit chip 300 is not covered with the resin layer 150. Then, the outer end 300E is exposed to the outside of the sealing region (three-dimensional region; sealing space) surrounded by the element substrate 100, the opposed substrate 200, and the outer end of the resin layer 150.

A gap G is provided between the element substrate 100 and the opposed substrate 200. The gap G is the region surrounded by the element substrate 100, the opposed substrate 200, and the resin layer 150. For this reason, the total region of the gap G and the resin layer 150 can be said to be the sealing region. Herein, when a second resin layer different from the resin layer 150 is filled in the gap G, it is possible to suppress the penetration of the moisture into the functional element 50. For the second resin layer, a given material can be used so long as it is transparent. The second resin layer is, for example, an acrylic resin or an epoxy resin. The thickness of the second resin layer (gap G) is larger than the thickness of the driving circuit chip 300. The driving circuit chip 300 is not in contact with the gap G.

The joint member 451 is an ACF (anisotropic conductive film), solder, or the like. Application of the joint member 451 with a heat and a pressure causes thermal press-bonding of the first terminal part 31 and the joint electrode of the driving circuit chip 300. As a result of this, the first terminal part 31 and the joint electrode of the driving circuit chip 300 are electrically connected with each other.

The joint member 452 is an ACF (anisotropic conductive film), solder, or the like as with the joint member 451. Thermal press-bonding establishes an electric connection between the second terminal part 32 of the element substrate 100 and the copper electrode of the wiring substrate 400.

Regarding Detailed Configuration of Element Substrate 100

Subsequently, a description will be given to the detailed configuration of the element substrate 100. The element substrate 100 has, as described above, the substrate 10, the semiconductor element 20, the wiring layer 30, the first terminal part 31, the second terminal part 32, the interlayer insulation layer 40, and the functional element 50.

The substrate 10 includes a semiconductor such as single crystal silicon.

The semiconductor element 20 includes a transistor, a diode, and the like. A part of the semiconductor element 20 is provided in the substrate 10.

The wiring layer 30 includes a multilayer wiring layer (such as an aluminum layer or a copper layer), and a plug (such as a via plug or a contact plug).

The first terminal part 31 and the second terminal part 32 are each, for example, a terminal member formed with a multilayer wiring layer and a plug as with the wiring layer 30.

The interlayer insulation layer 40 includes a plurality of interlayer insulation layers. The interlayer insulation layer 40 includes a silicon oxide layer, a silicon nitride layer, a silicon carbide layer, or the like. Incidentally, silicon oxynitride and silicon carbonitride each include nitrogen and silicon as main elements, and hence each can be said to be a kind of silicon nitride. In the effective element region AA of the element substrate 100, the functional element 50 is provided.

The functional element 50 is a display element, a photoelectric conversion element, or the like. As the display element, an EL element in an ELD (electroluminescence display), a liquid crystal element in a LCD (liquid crystal display), a reflection element in a DMD (digital mirror device), or the like can be used. Incidentally, in embodiment 1, the functional element 50 is assumed to be driven as an effective element. Then, the non-effective element may have the same configuration as that of the effective element.

The functional element 50 is connected with the wiring layer 30 via a via (not shown) provided in the interlayer insulation layer 40. Then, the functional element 50 is electrically connected with the semiconductor element 20 via the wiring layer 30. Further, on (on the opposed substrate 200 side of) the functional element 50, a passivation film (a film for suppressing penetration of the moisture, oxygen, or the like), a color filter layer, a lens structure, or the like can also be appropriately provided.

Regarding Method for Manufacturing Organic EL Display Device

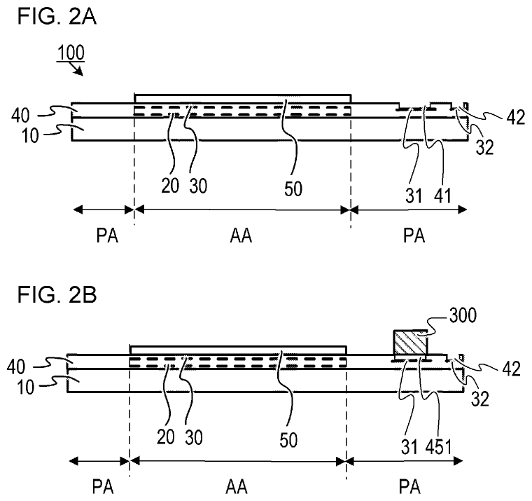

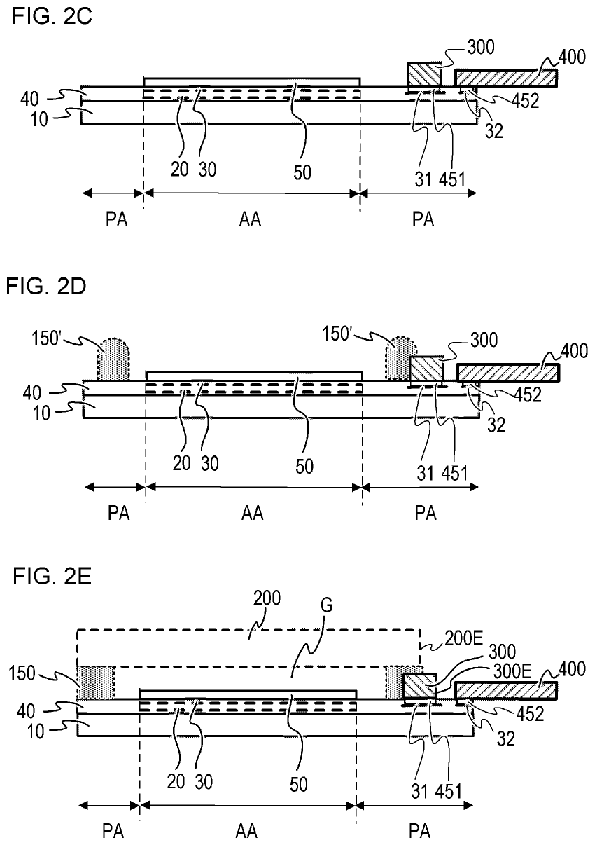

A description will be given to the method for manufacturing the semiconductor device 800 regarding the case where the semiconductor device 800 is an organic EL display device (organic light-emitting element) with reference to FIGS. 2A to 2E. The semiconductor device 800 is manufactured by performing the following steps (1) to (10).

(1) A substrate 10 formed of silicon or the like is prepared. Then, on the first main surface of the substrate 10, a semiconductor element 20 including a transistor, and the like is formed.

(2) On the semiconductor element 20 and the first main surface of the substrate 10, an interlayer insulation layer 40 is formed. Herein, for the interlayer insulation layer 40, silicon oxide, silicon nitride, silicon carbide, or the like is used. Further, the interlayer insulation layer 40 is provided with a contact plug (not shown) electrically connected with the semiconductor element 20. In the contact plug, a conductive member of tungsten or the like is buried.

(3) In the inside of the interlayer insulation layer 40, a wiring layer 30 is provided. The wiring layer 30 is electrically connected with the semiconductor element 20 via the contact plug. For the wiring layer 30, a metal member of aluminum, copper, or the like is used. Incidentally, in order to suppress the metal diffusion into the interlayer insulation layer 40 by the wiring layer 30, a barrier metal may be provided at the interface between the interlayer insulation layer 40 and the wiring layer 30. For the barrier metal, Ti, Ta, TiN, TaN, or the like can be used.

(4) In the same manner as the method for manufacturing the wiring layer 30 in the peripheral region PA of the substrate 10, a first terminal part 31 and a second terminal part 32 are formed. On the first terminal part 31 and the second terminal part 32, there are provided openings from which the interlayer insulation layer 40 has been removed (a first opening 41 and a second opening 42). As a result, the first terminal part 31 and the second terminal part 32 are exposed.

(5) On the interlayer insulation layer 40 in the effective element region AA, a functional element 50 of an organic EL element is provided. The functional element 50 is electrically connected with at least the wiring layer 30 via a through hole (not shown). The functional element 50 includes a pixel electrode, an opposed electrode, and an organic light-emitting layer (not shown). The organic light-emitting layer is provided between the pixel electrode and the opposed electrode. Incidentally, in order to facilitate injection and transport of positive holes from the pixel electrode, a hole injection layer and a hole transport layer may be formed between the organic light-emitting layer and the pixel electrode. Further, in order to facilitate injection and transport of electrons from the opposed electrode, an electron transport layer and an electron injection layer may be formed between the organic light-emitting layer and the opposed electrode.

(6) On the functional element 50, a sealing passivation film (not shown) for suppressing the penetration of the moisture is formed. On the passivation film, a color filter layer or a lens structure (a structure for enhancing the light-extraction efficiency) may be provided.

Up to this point, through the steps (1) to (6), an element substrate 100 shown in FIG. 2A is formed (prepared). Incidentally, the order of the steps (1) to (6) may be rearranged arbitrarily if not virtually impossible.

(7) As shown in FIG. 2B, on the first terminal part 31 of the element substrate 100, as a joint member 451, an ACF (an anisotropic conductive film) is bonded. Further, the main surface (the main surface of the driving circuit chip 300) including a joint electrode (not shown) formed thereon is opposed to the element substrate 100. Then, the driving circuit chip 300 is thermally press-bonded to the first terminal part 31 via the joint member 451. At this step, the thermal press-bonding temperature is, for example, 100° C. so as to prevent deterioration of the functional element 50 of an organic EL element due to a heat.

Further, the ACF includes a conductive particle in an epoxy resin binder. For this reason, the conductive particle establishes an electric connection between the first terminal part 31 and the driving circuit chip 300. Herein, the resin binder of the ACF is a resin different from that of the resin layer 150. Further, when the first terminal part 31 of the element substrate 100 and the joint electrode of the driving circuit chip 300 are joined by solder, an underfill resin may be injected into the joint part. Incidentally, the underfill resin is also a resin different from that of the resin layer 150.

(8) As shown in FIG. 2C, onto the second terminal part 32 of the element substrate 100, an ACF is bonded as a joint member 452. Further, the surface including an electrode (not shown) formed thereon of the main surface of the wiring substrate 400 is allowed to be opposed to the element substrate 100. Then, the wiring substrate 400 is thermally press-bonded to the second terminal part 32 via the joint member 452. Also in the present step, for example, the press-bonding temperature is 100° C. so as to prevent the deterioration of the functional element 50 (organic EL element) due to a heat. The conductive particle included in the epoxy resin of the ACF establishes an electric connection between the second terminal part 32 and the wiring substrate 400. As the wiring substrate 400, a flexible circuit substrate can be used. In the flexible circuit substrate, a copper wiring pattern is formed on a polyimide base material.

Here, the resin binder of the ACF is different from the resin of the resin layer 150. Further, when the second terminal part 32 of the element substrate 100 and the joint electrode of the wiring substrate 400 are joined by solder, an underfill resin may be injected into the joint part. The underfill resin is different from the resin of the resin layer 150.

(9) As shown in FIG. 2D, in order to form the resin layer 150, a resin material 150′ is coated to the peripheral region PA of the element substrate 100. The resin material 150′ is coated in a frame shape in a plan view in such a manner as to surround the effective element region AA. At the side to be provided with a driving circuit chip 300 of the resin material 150′, the resin material 150′ is coated so as to be in contact with the side surface on the effective element region AA side of the driving circuit chip 300.

The resin material 150′ is provided with a thickness equal to, or larger than the thickness of the driving circuit chip 300. If the resin material 150′ with a thickness smaller than the thickness of the driving circuit chip 300 is formed, in a bonding step of the opposed substrate 200 described later, the opposed substrate 200 comes in direct contact with the driving circuit chip 300. For this reason, a gap may be caused between the resin material 150′ and the opposed substrate 200, which may cause poor bonding. Generally, the driving circuit chip 300 has a thickness of 100 μm or more. For this reason, the resin material 150′ is also required to be coated with a thickness of 100 μm or more. Accordingly, in order to form the resin material 150′ with a thickness of 100 μm or more, for the resin material 150′, a material having a viscosity of 10000 mPa·s or more may desirably be used. For the resin material 150′, further preferably, a material having a viscosity of 100000 mPa·s or more is preferably used. Then, for the coating method of the resin material 150′, a dispense system can be used. As the resin material 150′, a given resin material such as an epoxy resin or an acrylic resin can be used. Incidentally, in embodiment 1, the thickness of the driving circuit chip 300 is 220 μm. For this reason, the coating conditions are adjusted so that the film thickness upon coating the resin material 150′ may become 350 μm.

(10) As shown in FIG. 2E, the opposed substrate 200 is bonded to the resin material 150′ so as to be opposed to the element substrate 100. Subsequently, the resin material 150′ is cured. Herein, the load of the opposed substrate 200 spreads the resin material 150′ in the horizontal direction (the left-right direction of FIG. 2E), so that the resin material 150′ gets wet and spreads in the gap between the upper surface (the surface opposed to the opposed substrate 200) of the driving circuit chip 300 and the opposed substrate 200. This results in a state in which the resin material 150′ covers a part of the upper surface of the driving circuit chip 300.

Specifically, the outer end 200E of the opposed substrate 200 is arranged so as to be situated on the upper surface of the driving circuit chip 300. Then, the resin material 150′ and the opposed substrate 200 are bonded to each other so as to prevent the resin material 150′ from protruding to the outside of the outer end 200E of the opposed substrate 200. Subsequently, in this state, the resin material 150′ is cured by an ultraviolet ray, thereby forming the resin layer 150.

In embodiment 1, after the completion of the bonding step of the opposed substrate 200, the film thickness of the resin layer 150 arranged between the driving circuit chip 300 and the effective element region AA is 250 μm. The film thickness of the resin layer 150 arranged between the opposed substrate 200 and the upper surface of the driving circuit chip 300 is about 30 μm.

By the steps (1) to (10) (manufacturing method) up to this point, the semiconductor device 800 (the organic EL display device) in accordance with embodiment 1 is completed.

As described up to this point, a part of the resin layer 150 for bonding the element substrate 100 and the opposed substrate 200 is superposed on the driving circuit chip 300 in a plan view. This can more save the space of the peripheral region PA of the element substrate 100 as compared with the case where the formation region of the resin layer 150 and the arrangement region of the driving circuit chip 300 are arranged in parallel with each other.

Further, a part of the driving circuit chip 300 is covered with the opposed substrate 200. For this reason, the external damage of the driving circuit chip 300 is reduced. Further, a part of the driving circuit chip 300 is not covered with the resin layer 150, and is exposed to the outside air. For this reason, the heat radiated from the driving circuit chip 300 can be radiated with efficiency.

As described up to this point, in accordance with embodiment 1, it is possible to achieve space saving of the element substrate 100, which enables combination of the protection of the driving circuit chip 300 from external damage and heat radiation therefrom.

### Embodiment 2

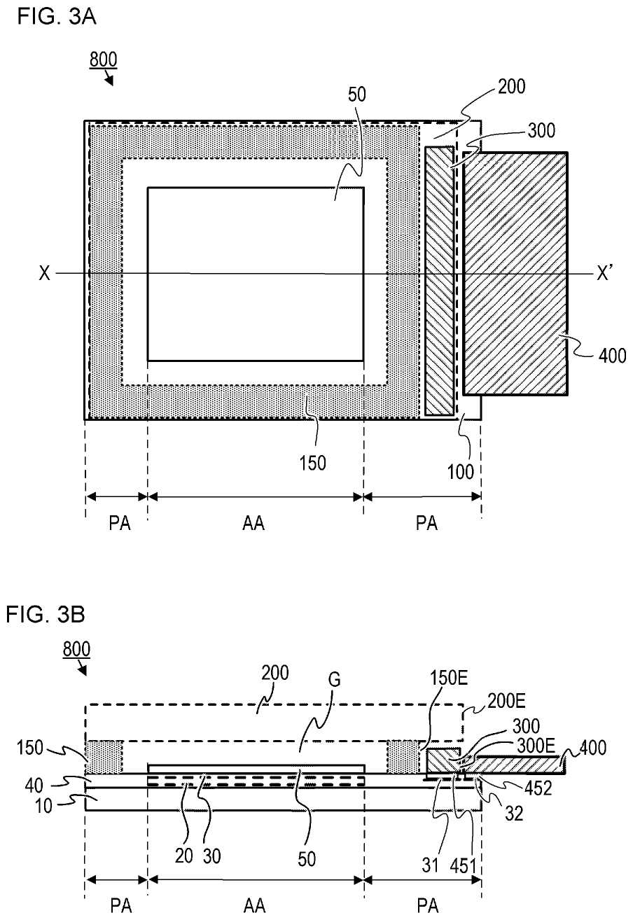

A semiconductor device 800 in accordance with embodiment 2 will be described with reference to FIGS. 3A and 3B. In embodiment 2, a resin layer 150 is not in contact with a driving circuit chip 300, and in a plan view, an opposed substrate 200 is superposed on the whole of the driving circuit chip 300. Of the description regarding embodiment 2, the description of the contents overlapping the contents of embodiment 1 will be omitted.

FIG. 3A shows a plan view of the semiconductor device 800 in accordance with embodiment 2. FIG. 3B is a cross sectional view of the semiconductor device 800 along line X-X′ of FIG. 3A. As shown in FIG. 3A, the resin layer 150 is not in contact with the driving circuit chip 300, and is arranged between the driving circuit chip 300 and the effective element region AA.

Then, the opposed substrate 200 covers the whole of the driving circuit chip 300 in a plan view. In other words, as shown in FIG. 3B, the outer end 200E of the opposed substrate 200 is at the same position as that of, or outside the outer end 300E of the driving circuit chip 300. For this reason, the opposed substrate 200 can suppress the external damage of the driving circuit chip 300.

Further, a gap is present between the outer end 150E of the resin layer 150 and the driving circuit chip 300, and another gap is also present between the upper surface of the driving circuit chip 300 and the opposed substrate 200. Therefore, a large area of the surface of the driving circuit chip 300 is in contact with the outside air. For this reason, the heat of the driving circuit chip 300 can be radiated with efficiency.

In embodiment 2, the opposed substrate 200 covers the driving circuit chip 300. For this reason, the external damage of the driving circuit chip 300 can be reduced more than in embodiment 1. Further, the large region of the surface of the driving circuit chip 300 is in contact with the outside air. For this reason, the heat radiation property of the driving circuit chip 300 is improved.

### Embodiment 3

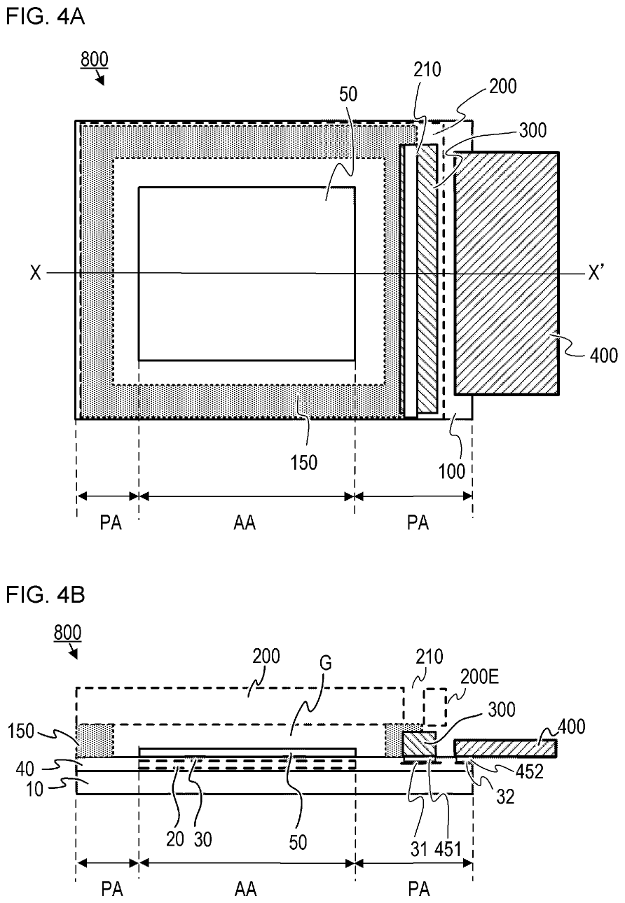

A semiconductor device 800 in accordance with embodiment 3 will be described with reference to FIGS. 4A and 4B. In embodiment 3, an opening 210 penetrating through an opposed substrate 200 in the thickness direction thereof is provided in the superposing region between the opposed substrate 200 and a driving circuit chip 300 in a plan view. Of the description regarding embodiment 3, the contents overlapping the contents of embodiment 1 will be omitted.

FIG. 4A shows a plan view of the semiconductor device 800 in accordance with embodiment 3. FIG. 4B is a cross sectional view of the semiconductor device 800 along line X-X′ shown in FIG. 4A. As shown in FIG. 4A, the opposed substrate 200 is provided with the opening 210. The opening 210 causes the resin layer 150 provided on the upper surface of the driving circuit chip 300 to be exposed to (to communicate with) the external space. When glass is used as the opposed substrate 200, the opening 210 can be formed by wet etching with hydrofluoric acid or machining. The opening 210 causes the resin layer 150 provided on the upper surface of the driving circuit chip 300 to be exposed to the outside air. For this reason, it is possible to improve the heat radiation property of the driving circuit chip 300.

Incidentally, in FIG. 4B, the resin layer 150 is arranged between the upper surface of the driving circuit chip 300 and the opening 210 of the opposed substrate 200. However, the resin layer 150 is not required to be provided between the upper surface of the driving circuit chip 300 and the opening 210 of the opposed substrate 200. The resin layer 150 is not provided between the upper surface of the driving circuit chip 300 and the opening 210 of the opposed substrate 200 (a gap is provided). This can further improve the heat radiation property of the driving circuit chip 300.

In accordance with embodiment 3, it is possible to achieve the space saving of the peripheral region PA, and it is possible to suppress the external damage of the driving circuit chip 300. Further, the heat radiation property of the driving circuit chip 300 is improved.

### Embodiment 4

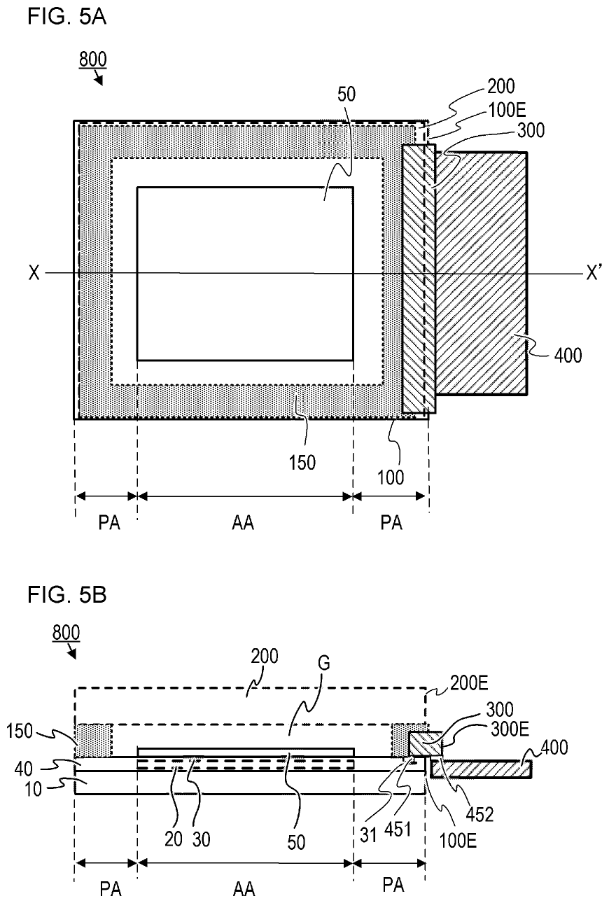

A semiconductor device 800 in accordance with embodiment 4 will be described with reference to FIGS. 5A and 5B. In embodiment 4, the outer end 300E of the driving circuit chip 300 protrudes to the outside of the outer end 100E of the element substrate 100. In the protruding region, the driving circuit chip 300 and the wiring substrate 400 are joined with each other. Of the description regarding embodiment 4, the contents overlapping the contents of embodiments 1 to 3 will be omitted.

FIG. 5A shows a plan view of the semiconductor device 800 in accordance with embodiment 4. FIG. 5B is a cross sectional view of the semiconductor device 800 along line X-X′ of FIG. 5A. As shown in FIG. 5A, the outer end 300E of the driving circuit chip 300 protrudes to the outside of the outer end 100E of the element substrate 100. In other words, while in a plan view, a part of the driving circuit chip 300 is superposed on the element substrate 100, other parts thereof protrude to the outside of the element substrate 100. Herein, the region of the driving circuit chip 300 not superposed on the element substrate 100 is assumed to be a protruding region (protruding part). Then, in the protruding region of the driving circuit chip 300, the driving circuit chip 300 and the wiring substrate 400 are electrically connected with each other. The driving circuit chip 300 and the wiring substrate 400 are superposed one on another in the region including a joint member 452 in FIG. 5B present therein.

The opposed substrate 200 and the resin layer 150 cover only one side surface on the effective element region AA side of the driving circuit chip 300. In other words, the outer end 300E of the driving circuit chip 300 is not covered with the resin layer 150, and is exposed to the outside air. For this reason, it is possible to improve the heat radiation property of the driving circuit chip 300.

As shown in FIG. 5B, the first terminal part 31 of the element substrate 100 and the driving circuit chip 300 are electrically connected with each other via the joint member 451. Further, in the protruding region of the driving circuit chip 300, the driving circuit chip 300 and the wiring substrate 400 are electrically connected with each other via the joint member 452. Herein, for the joint member 451 and the joint member 452, an ACF can be used.

In accordance with embodiment 4, the junction region with the wiring substrate 400 is not required to be provided in the peripheral region PA of the element substrate 100. For this reason, it is possible to achieve more space saving of the peripheral region PA of the element substrate 100 in peripheral region PA than in embodiment 1.

Up to this point, in embodiments 1 to 4, it is possible to implement space saving of the element substrate when the formation region of the resin layer for bonding the element substrate and the opposed substrate and the driving circuit chip are superposed one on another. Further, at least a part of the top of the driving circuit chip is covered with the opposed substrate. This can suppress the damage of the driving circuit chip. At least one end of the driving circuit chip is not covered with the resin layer, and is exposed to the outside air. This improves the heat radiation property of the driving circuit chip. As a result, it is possible to suppress the damage of the semiconductor device, and it is possible to achieve the improvement of the quality and the reliability of the semiconductor device.

### Embodiment 5

In embodiment 5, a description will be given to various devices to which the semiconductor device 800 of any of embodiments 1 to 4 is applied to an organic light-emitting element. In other words, the organic light-emitting element in accordance with the present embodiment is one example of the semiconductor device 800.

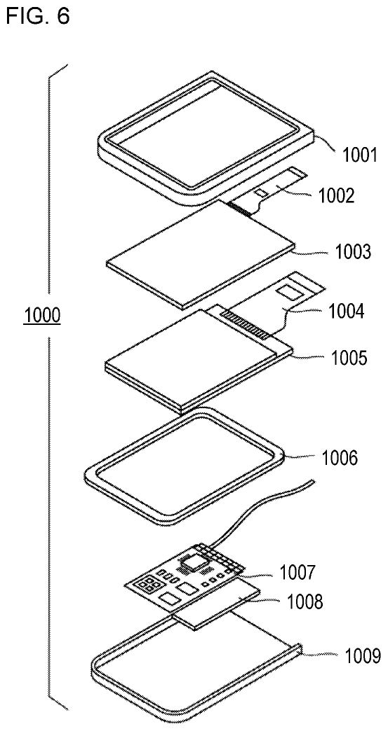

FIG. 6 is a schematic view showing one example of a display device in accordance with the present embodiment. A display device 1000 has a plurality of pixels. The display device 1000 has a touch panel 1003, a display panel 1005, a frame 1006, a circuit substrate 1007, and a battery 1008 between an upper cover 1001 and a lower cover 1009. The touch panel 1003 is connected with a flexible print circuit FPC 1002. The display panel 1005 is connected with a flexible print circuit FPC 1004. A transistor is printed on the circuit substrate 1007. At least some of the plurality of pixels of the display device 1000 may have an organic light-emitting element in accordance with the present embodiment, and a transistor connected with the organic light-emitting element. Incidentally, when the display device 1000 is not portable equipment, the display device 1000 is not required to be provided with the battery 1008. On the other hand, even when the display device 1000 is portable equipment, the battery 1008 may be provided at a different position from the position shown in FIG. 6.

The display device in accordance with the present embodiment may have a color filter having a red color, a green color, and a blue color. The color filter may be a filter including a red color, a green color, and a blue color arranged in a delta arrangement.

The display device 1000 in accordance with the present embodiment may be used for the display part of a portable terminal. In that case, the display device 1000 may have both of the display function and the operation function. The portable terminal is, for example, a cellular phone (such as a smartphone), a tablet or a head mount display.

The display device 1000 in accordance with the present embodiment may be used for the display part of an image pick-up device. The image pick-up device has, for example, an optical part (optical member) having a plurality of lenses, and an image pick-up element for receiving a light which has passed through the optical part. The image pick-up device may have a display part for displaying the information acquired by the image pick-up element. Further, the display part may be either the display part exposed to the outside of the image pick-up device, or the display part arranged in a finder. The image pick-up device is, for example, a digital camera or a digital video camera.

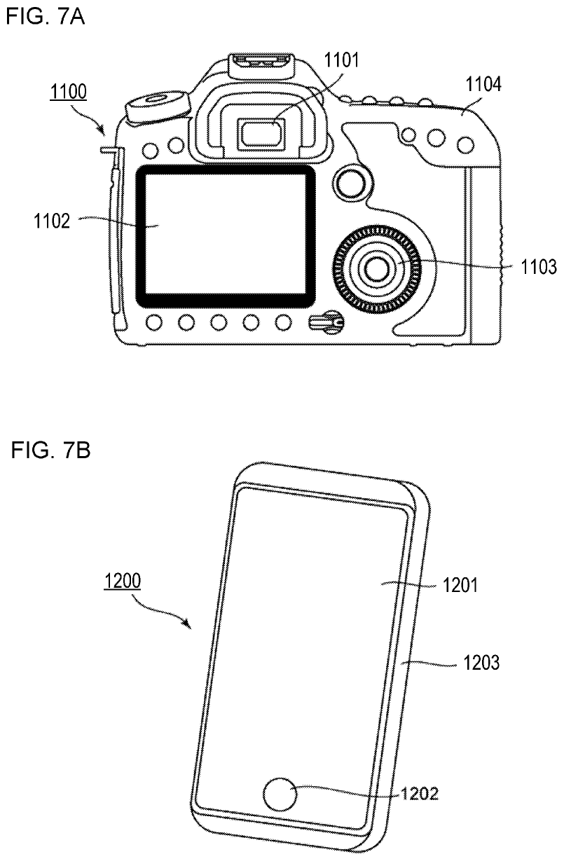

FIG. 7A is a schematic view showing one example of the image pick-up device in accordance with the present embodiment. An image pick-up device 1100 has a view finder 1101, a back surface display 1102, an operating part 1103, and a housing 1104. The view finder 1101 may have a display device 1000 in accordance with the present embodiment. In that case, the display device 1000 may display not only an image to be picked up, but also environmental information, image pick-up directions, or the like. The environmental information is, for example, information such as the intensity of outside light, the direction of outside light, the moving speed of the subject, or the possibility of the subject being shielded by a shield.

Incidentally, the timings preferable for image pick-up are less. For this reason, information is preferably displayed as soon as possible. Therefore, it is preferable to use a display device using the organic light-emitting element in accordance with the present embodiment for at least one pixel. The organic light-emitting element is high in speed of response. For this reason, the display device using the organic light-emitting element can be more preferably used for image pick-up than other devices required to have a desirable display speed (e.g., a liquid crystal display device).

The image pick-up device 1100 has an optical part not shown. The optical part has a plurality of lenses, and forms an image on the image pick-up element accommodated in the housing 1104. The plurality of lenses can be adjusted in focus by adjusting the relative positions thereof. The image pick-up device 1100 can also perform this operation automatically. The image pick-up device 1100 may be referred to as a photoelectric conversion device. With the photoelectric conversion device, not only the method for sequential image pick-up, but also the method for detecting the difference from the previous image, the method of capture from the image continuously recorded, or other methods can be used as the method of image pick-up.

FIG. 7B is a schematic view showing one example of the electronic equipment in accordance with the present embodiment. Electronic equipment 1200 has a display part 1201, an operating part 1202, and a housing 1203. The housing 1203 may have a print substrate (a print substrate having a circuit), a battery, and a communication part (communication device). The operating part 1202 may be a button, or a reaction part of a touch panel system. The operating part 1202 may be a biometric identification part for identifying the fingerprint, and performing lock release, or the like.

The electronic equipment having a communication part can also be said to be communication equipment. The electronic equipment may further have a camera function by including a lens and an image pick-up element. The image picked up by the camera function is displayed at the display part. The electronic equipment is, for example, a smartphone or a notebook personal computer.

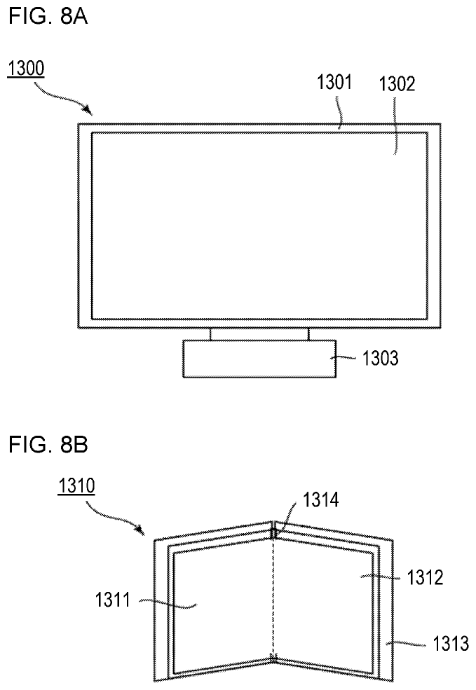

FIG. 8A is a schematic view showing one example of the display device in accordance with the present embodiment. FIG. 8A shows a display device 1300 such as a television monitor or a PC monitor. The display device 1300 has a frame 1301 and a display part 1302. The display part 1302 may have the organic light-emitting element in accordance with the present embodiment.

The display device 1300 has a base 1303 for supporting the frame 1301 and the display part 1302. The base 1303 is not limited to the aspect shown in FIG. 8A. The lower side of the frame 1301 may also serve as the base.

Further, the frame 1301 and the display part 1302 may be curved. The curvature radius may be at least 5000 mm and not more than 6000 mm.

FIG. 8B is a schematic view showing another example of the display device in accordance with the present embodiment. A display device 1310 of FIG. 8B is configured bendably, and is a so-called foldable display device. The display device 1310 has a first display part 1311, a second display part 1312, a housing 1313, and a bending point 1314. The first display part 1311 and the second display part 1312 may have the organic light-emitting element in accordance with the present embodiment. The first display part 1311 and the second display part 1312 may be one seamless display device. The first display part 1311 and the second display part 1312 can be separated from each other at the bending point 1314. The first display part 1311 and the second display part 1312 may display mutually different images, respectively. Further, the first display part 1311 and the second display part 1312 may display one image.

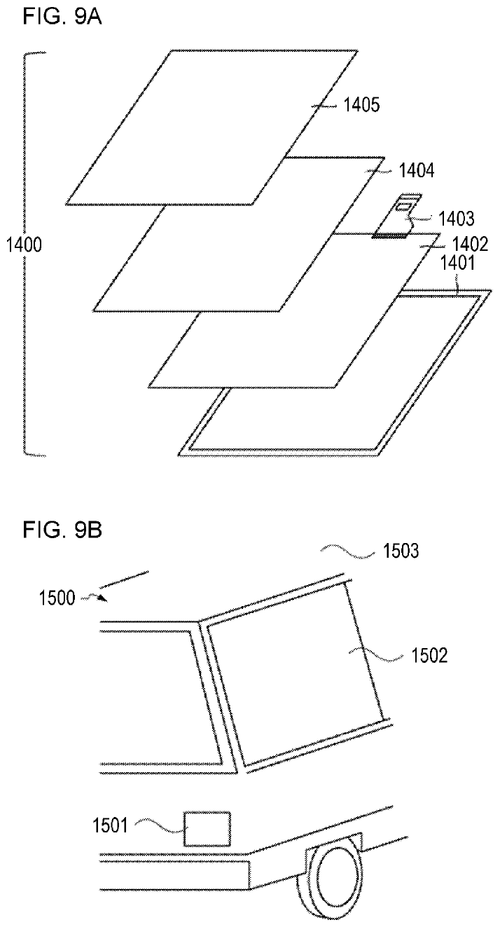

FIG. 9A is a schematic view showing one example of an illuminating device in accordance with the present embodiment. An illuminating device 1400 has a housing 1401, a light source 1402, a circuit substrate 1403, an optical filter 1404, and a light diffusion part 1405. The light source 1402 has an organic light-emitting element in accordance with the present embodiment. The optical filter 1404 may be a filter for improving the color rendering properties of the light source 1402. The light diffusion part 1405 can effectively diffuse a light from the light source 1402 and can deliver the light to a wide region by illumination or the like. The optical filter 1404 and the light diffusion part 1405 transmit a light from the light source 1402 therethrough. The optical filter 1404 and the light diffusion part 1405 may be provided on the light emitting side of illumination. If required, the outermost part of the illuminating device 1400 may be provided with a cover.

The illuminating device is, for example, a device for illuminating the interior of a room. The illuminating device may emit a light of white, neutral white, or any other color of from blue to red. The illuminating device may have a dimmer circuit for modulating a light. The illuminating device may have an organic light-emitting element, and a power supply circuit to be connected with the organic light-emitting element. The power supply circuit is a circuit for converting an alternating voltage to a direct current voltage. Further, white is a color with a color temperature of 4200 K, and neutral white is a color with a color temperature of 5000 K. The illuminating device may have a color filter.

Further, the illuminating device in accordance with the present embodiment may have a heat radiating part. The heat radiating part radiates the heat in the illuminating device to the outside of the illuminating device. For the radiating part, a metal with a high specific heat, liquid silicon, or the like can be used.

FIG. 9B is a schematic view of an automobile of one example of a mobile object in accordance with the present embodiment. An automobile 1500 has a table lamp 1501 of one example of lighting fixtures. The automobile 1500 turns on the table lamp 1501, for example, upon performing a braking operation.

The table lamp 1501 has an organic light-emitting element in accordance with the present embodiment. The table lamp 1501 may have a protective member for protecting the organic light-emitting element. The protective member may preferably include polycarbonate or the like although any material is acceptable so long as the material has a certain degree of high strength, and is transparent. Polycarbonate may be mixed with a furan dicarboxylate derivative, acrylonitrile derivative, or the like.

The automobile 1500 has a car body 1503 and a window 1502 (a window mounted on the car body 1503). The window 1502 may be a transparent display unless it is a window for checking the front and the rear of the automobile. A transparent display has, for example, the organic light-emitting element in accordance with the present embodiment. In this case, the constituent material of an electrode included in the organic light-emitting element, or the like includes a transparent member.

The mobile object in accordance with the present embodiment may be a ship, an aircraft, a drone, or the like. The mobile object may have a body (an airframe) and a lighting fixture provided on the body. The lighting fixture may emit a light for making the position of a body known. The lighting fixture has the organic light-emitting element in accordance with the present embodiment.

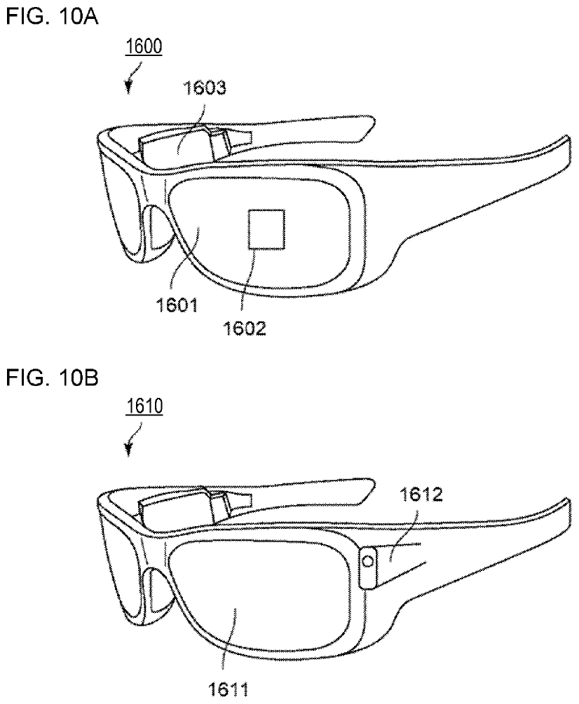

Referring to FIGS. 10A and 10B, a description will be given to the application example of the display device of the present embodiment. The display device is applicable to a system mountable as a wearable device (e.g., smart glasses, a HMD, or a smart contact). The device for use in such an application example has an image pick-up device capable of photoelectrically converting a visible light, and a display device capable of emitting a visible light.

FIG. 10A illustrates glasses 1600 (smart glasses) in accordance with one application example. An image pick-up device 1602 such as a CMOS sensor or a SPAD is provided on the front surface side of each lens 1601 of the glasses 1600. Further, the display device of the present embodiment is provided on the back surface side of the lens 1601.

The glasses 1600 further include a control device 1603. The control device 1603 functions as a power source for supplying an electric power to the image pick-up device 1602 and the display device in accordance with the present embodiment. Further, the control device 1603 controls the operations of the image pick-up device 1602 and the display device. In the lens 1601, an optical system for condensing a light to the image pick-up device 1602 is formed.

FIG. 10B illustrates glasses 1610 (smart glasses) in accordance with one application example. The glasses 1610 have a control device 1612. On the control device 1612, the image pick-up device (corresponding to the image pick-up device 1602), and a display device are mounted. In the lens 1611, an optical system for projecting light emission from the display device in the control device 1612 is formed, so that an image is projected on the lens 1611. The control device 1612 functions as a power source for supplying an electric power to the image pick-up device and the display device, and controls the operations of the image pick-up device and the display device. The control device 1612 may have a line-of-sight detecting part for detecting the line of sight of a wearer. For the detection of the line of sight, an infrared ray may be used. An infrared ray emitting part emits an infrared ray with respect to each eyeball of a user carefully watching the display image. The image pick-up part having a photo acceptance unit detects the reflected light from the eyeball of the emitted infrared ray, resulting in an image picked-up image of the eyeball. Further, the glasses 1610 have a reducing means of reducing the light from the infrared ray emitting part in a plan view, thereby reducing the reduction of the appearance of the image.

The line-of-sight detecting part detects the line of sight of a user with respect to the display image from the image picked-up image of the eyeball acquired by image pick-up with an infrared ray. To the detection of the line-of-sight using the image picked-up image of the eyeball, a given known method is applicable. As one example of the line-of-sight detecting method, the line-of-sight detecting method based on the Purkinje image by reflection of an irradiation light at the cornea can be used.

More specifically, line-of-sight detecting processing based on the pupil cornea reflection method is performed. Using the pupil cornea reflection method, based on the image of the pupil included in the image picked-up image of the eyeball, and the Purkinje image, the line-of-sight vector indicative of the direction (rotation angle) of the eyeball is calculated, thereby detecting the line of sight of a user.

The display device in accordance with one embodiment of the present invention has an image pick-up device having a photo acceptance unit, and may control the display image of the display device based on the line-f-sight information of a user from the image pick-up device.

Specifically, based on the line-of-sight information, the first field-of-view region watched carefully by a user, and the second field-of-view region other than the first field-of-view region are determined. The first field-of-view region and the second field-of-view region may be determined by the control device of the display device, or the display device may receive the one determined by an external control device. The display device may control the display resolution of the first field-of-view region higher than the display resolution of the second field-of-view region in the display region. In other words, the display device may set the resolution of the second field-of-view region lower than that of the first field-of-view region.

Further, the display region has a first display region, and a second display region different from the first display region. Based on the line-of-sight information, the region with a higher priority is determined from the first display region and the second display region. The first display region and the second display region may be determined by the control device of the display device, or the display device may receive the one determined by an external control device. The display device may control the resolution of the region with a higher priority higher than the resolution of the region other than the region with a higher priority. In other words, the display device may set the resolution of the region with a relatively lower priority lower.

Incidentally, for the determination of the first field-of-view region or the region with a higher priority, AI may be used. AI may be a model configured such that with the image of the eyeball, and the direction in which the eyeball of the image actually saw as teacher data, the angle of the line of sight from the image of the eyeball, and the distance to the object beyond the line of sight are estimated. The AI program may be possessed by any of the display device, the image pick-up device, and an external device. When the external device has an AI program, the determination result using the AI program is transmitted to the display device via communication.

When the smart glasses control the display based on the visual recognition detection, the smart glasses may further have an image pick-up device for performing image pick-up of the outside. According to this, the smart glasses can display the image picked-up external information on a real-time basis.

Up to this point, by using the organic light-emitting element in accordance with the present embodiment (the semiconductor device 800 in accordance with any of embodiments 1 to 4) for various devices, it becomes possible to perform stable display even for long-time display with a favorable image quality.

In accordance with the respective embodiments, it is possible to suppress the damages and the characteristic deterioration in a semiconductor device.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-048568, filed on Mar. 24, 2022, which is hereby incorporated by reference herein in its entirety.

What is claimed is:

1. A semiconductor device comprising:
an element substrate having a first region provided with a functional element, and a second region which is a peripheral region in a periphery of the first region;
an opposed substrate arranged so as to be superposed on the first region and at least a part of the second region in a plan view with respect to a main surface of the element substrate;
a resin layer arranged between the opposed substrate and the second region, and for bonding the opposed substrate and the second region; and
a driving circuit chip joined with the second region, wherein
the driving circuit chip has a region superposed on the opposed substrate in the plan view, and
the driving circuit chip has a region separated from the first region by a longer distance than a distance between the first region and the resin layer, the region being not superposed on the resin layer in the plan view.

2. The semiconductor device according to claim 1, wherein
the driving circuit chip has a third region covered with the resin layer, and
the driving circuit chip is exposed from the resin layer in a region separated from the first region by a longer distance than a distance between the first region and the third region.

3. The semiconductor device according to claim 1, wherein
a part of the resin layer is arranged between the first region and the driving circuit chip in the plan view.

4. The semiconductor device according to claim 1, wherein
a gap surrounded by the element substrate, the opposed substrate, and the resin layer is provided.

5. The semiconductor device according to claim 4, wherein
the driving circuit chip is exposed from a total region of the gap and the resin layer.

6. The semiconductor device according to claim 4, wherein
the gap is provided with a second resin layer different from the resin layer.

7. The semiconductor device according to claim 4, wherein
the driving circuit chip is not in contact with the gap.

8. The semiconductor device according to claim 1, wherein
the second region is provided with a terminal member, and
the terminal member and the driving circuit chip are joined with each other by an anisotropic conductive resin.

9. The semiconductor device according to claim 1, wherein
a opening is provided in a part, where the opposed substrate and the driving circuit chip are superposed in the plan view, of the opposed substrate, and
the opening penetrates the opposed substrate in a direction perpendicular to a main surface of the opposed substrate.

10. The semiconductor device according to claim 9, wherein
the resin layer is not arranged between the opening and the driving circuit chip.

11. The semiconductor device according to claim 1, wherein
the driving circuit chip has a protruding region protruding to outside the element substrate in the plan view.

12. The semiconductor device according to claim 11, further comprising a wiring substrate, wherein
the protruding region is joined with the wiring substrate.

13. The semiconductor device according to claim 12, wherein
the protruding region and the wiring substrate are joined with each other by an anisotropic conductive resin.

14. The semiconductor device according to claim 1, wherein
the opposed substrate is superposed on a whole of the driving circuit chip in the plan view.

15. The semiconductor device according to claim 1, wherein
the functional element is a display element or a photoelectric conversion element.

16. A display device having a plurality of pixels, wherein
at least one of the plurality of pixels has the semiconductor device according to claim 1, and a transistor connected to the semiconductor device.

17. A photoelectric conversion device, comprising an optical part having a plurality of lenses; an image pick-up element for receiving a light which has passed through the optical part; and a display part for displaying an image picked up by the image pick-up element, and
comprising the semiconductor device according to claim 1.

18. Electronic equipment, comprising: a display part having the semiconductor device according to claim 1; a housing including the display part; and a communication part provided in the housing and for communicating externally.

19. An illuminating device, comprising a light source having the semiconductor device according to claim 1; and a light diffusion part or an optical film for transmitting therethrough a light emitted from the light source.

20. A mobile object, comprising: a lighting fixture having the semiconductor device according to claim 1, and a body including the lighting fixture.
